(19) United States
(12) Patent Application Publication
(10) Pub. No.: US 2011/0254014 A1
(43) Pub. Date: Oct. 20, 2011

(54) NITRIDE SEMICONDUCTOR WAFER AND NITRIDE SEMICONDUCTOR DEVICE

(75) Inventor: Tadayoshi TSUCHIYA, Ishioka-shi (JP)

(73) Assignee: Hitachi Cable, Ltd., Tokyo (JP)

(21) Appl. No.: 13/046,874

(22) Filed: Mar. 14, 2011

(30) Foreign Application Priority Data
Apr. 19, 2010 (JP) 2010-096248

(51) Int. Cl. H01L 29/12

(52) U.S. Cl. 257/76; 257/E29.068

(57) ABSTRACT

There is stably provided a nitride semiconductor wafer having a nitride semiconductor layer with high insulating properties, wherein a semi-insulating nitride semiconductor layer is provided on an insulating substrate, with a resistivity of 10 MΩcm or more and 100 MΩcm or less, and a film thickness of 0.1 μm or more and 1.5 μm or less.

The present application is based on Japanese patent application No. 2010-096248, filed on Apr. 19, 2010, the entire contents of which are hereby incorporated by reference.

### BACKGROUND OF THE INVENTION

1. Field of the Invention

The present invention relates to a nitride semiconductor wafer and a nitride semiconductor device, having a semi-insulating nitride semiconductor layer requiring a high resistivity.

2. Description of the Related Art

Gallium nitride (GaN) having a bandgap wider than the bandgap of a semiconductor material such as silicon (Si) and gallium arsenide (GaAs) has been used for high output application by utilizing its heat resistant property and a height of a breakdown voltage.

When an application of a nitride semiconductor is manufactured with high output, one layer or a plurality of layers of a growth control layer (buffer layer) are formed on an insulating or electrodoncudtive substrate, and thereafter a semi-insulating first nitride semiconductor layer is formed, and further thereon is formed one layer or a plurality of layers of a layer including an electroconductive or semi-insulating second nitride semiconductor. Thereafter, a processing process for manufacturing a desired high output device is performed.

As the desired high output device, for example, power HFET (Hetero-Field Effect Transistor) can be given. Particularly in the power HFET of recent years, in order to improve a pressure resistant property, high insulation characteristics of 100 MΩcm order far exceeding several dozen kΩcm have been required for the first semi-insulating nitride semiconductor layer.

For example, a non-doped GaN layer described in patent document 1 as described below is known as a semi-insulating nitride semiconductor layer with high resistivity or sheet resistance, used for the power HFET. The non-doped GaN layer used here is laminated to a film thickness of 2 μm at a crystal grown temperature of 1140° C., and an extremely high resistivity of 1×10⁸ Ωcm is shown by this GaN layer (for example, see patent document 1).
(Patent document 1) Japanese Patent Laid Open Publication No. 2006-4976 (for example, paragraph 0039 etc.)

According to a technique of the patent document 1, although the semi-insulating nitride semiconductor layer with high resistivity satisfying a requested performance can be experimentally formed on a substrate, stability as a manufacturing technique is not sufficient. For example, insulation characteristics of a formed layer is largely different in some cases, for example, depending on a variation of a state of a film-forming apparatus, with a fluctuation of a quantity of production. This is because as a result of repeatedly using the same apparatus, an unnecessary reaction byproduct is adhered to an inside of the film-forming apparatus, thus causing a temperature distribution of the inside of the apparatus to be varied or causing a gas flow to be changed due to an adhered substance.

Further, the insulation characteristics are also sometimes fluctuated by heat treatment such as activation annealing in a device processing process. For example, when a deep level exists in the semi-insulating nitride semiconductor layer due to a certain kind of impurities or specific crystal defects, semi-insulating properties are caused to be unstable if its activation state is changed due to heat treatment or the deep level itself is substantially reduced. Such an unstable state is not preferable in terms of a manufacture. As is found from the above-described conventional technique, an actual state is not a state that a resistivity higher than a resistivity of about several dozen kΩcm, for example a resistivity exceeding 100 MΩcm can be stably obtained.

### BRIEF SUMMARY OF THE INVENTION

In order to solve the above-described problem, an object of the present invention is to stably provide a nitride semiconductor wafer and a nitride semiconductor device having a nitride semiconductor layer with substantially high insulating properties.

According to an aspect of the present invention, a nitride semiconductor wafer is provided, having a semi-insulating nitride semiconductor layer on an insulting substrate, with a resistivity of 10 MΩcm or more and 100 MΩcm or less, a film thickness of 0.1 μm or more and 1.5 μm or less.

Further, according to other aspect of the present invention, a nitride semiconductor wafer is provided, having a semi-insulating nitride semiconductor layer on an electroconductive substrate, with a resistivity of 10 MΩcm or more and 100 MΩcm or less, and a film thickness of 0.5 μm or more and 1.5 μm or less.

In these cases, the film thickness of the semi-insulating nitride semiconductor layer is preferably set to be smaller than 1 μm.

Gallium nitride or aluminium nitride, or a nitride mixed crystal of gallium and aluminium can be used for the semi-insulating nitride semiconductor layer. However, a nitride mixed crystal of gallium and indium, or a nitride mixed crystal of aluminium and indium, or a nitride mixed crystal of gallium, aluminium, and indium may also be used for the semi-insulating nitride semiconductor layer.

Further, any one of silicon carbide, gallium nitride, and sapphire can be used for the insulating substrate, and silicon can be used for the electroconductive substrate.

Further, according to another embodiment, a nitride semiconductor device is provided, further comprising a nitride semiconductor layer on the nitride semiconductor wafer.

According to the present invention, the nitride semiconductor wafer and the nitride semiconductor device can be stably provided, having a nitride semiconductor layer with high insulating properties.

### BRIEF DESCRIPTION OF THE DRAWINGS

FIG. 1 is a cross-sectional view of a nitride semiconductor wafer having a semi-insulating nitride semiconductor layer according to an embodiment of the present invention.

FIG. 2 is a cross-sectional view of a nitride semiconductor device having a semi-insulating nitride semiconductor layer according to an embodiment of the present invention.

FIG. 3 is a cross-sectional view of a nitride semiconductor wafer having a semi-insulating nitride semiconductor layer according to other embodiment of the present invention.

### DETAILED DESCRIPTION OF THE INVENTION

As is already described, there is a case that insulating properties of a semi-insulating nitride semiconductor layer formed on a substrate are largely different, due to a change of a state of a film-forming apparatus, with a fluctuation of a quantity of production. As a result, if the semi-insulating nitride semiconductor layer with ultrahigh resistivity is obtained, resistivity can not be stably obtained. The semi-insulating nitride semiconductor layer with high resistivity formed on the substrate can be stably obtained by the present technique, provided that the resistivity is 100 MΩcm or less. However, the semi-insulating nitride semiconductor layer with high resistivity exceeding 100 MΩcm can hardly be obtained stably. According to an embodiment of the present invention, not only the resistivity but also the film thickness of the semi-insulating nitride semiconductor layer is an important element from a relation between a drain leak current suitable for an actual device structure and the resistivity, and based on this knowledge, a target resistivity to be achieved is clearly shown and the film thickness is defined without unnecessarily increasing the resistivity. By defining the film thickness, even in a case of the resistivity of 100 MΩcm or less considered to be insufficient before, it is found that an effect equivalent to high resistivity exceeding 100 MΩcm can be obtained. Thus, by defining not only the resistivity but also the film thickness, the nitride semiconductor wafer and the nitride semiconductor device having the semi-insulating nitride semiconductor layer with good insulation characteristics can be stably supplied.

An embodiment of the present invention will be described hereafter.

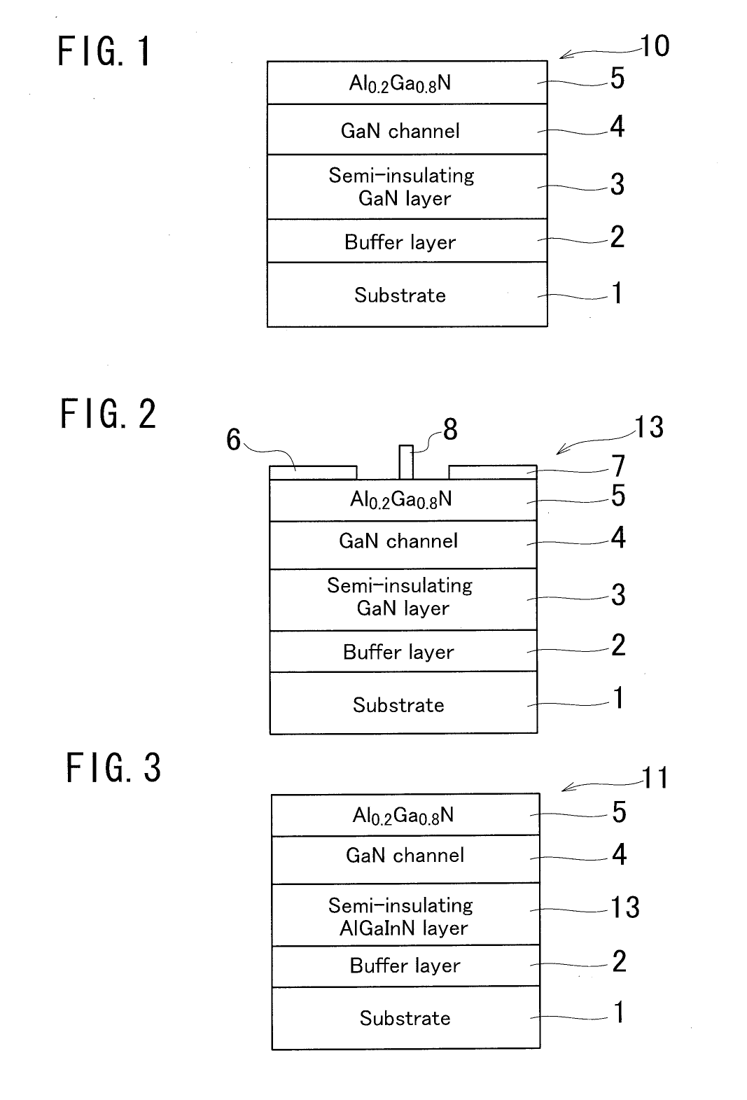

FIG. 1 shows a nitride semiconductor wafer 10 according to an embodiment of the present invention. The nitride semiconductor wafer 10 is sometimes formed as FET (Field Effect Transistor) or HFET (Hetero-FET), being a modified example of FET, and further a semiconductor light-emitting element or a semiconductor light-receiving element. In an example shown in the figure, a case of HFET is shown.

The nitride semiconductor wafer 10 has a lamination structure composed of a plurality of epitaxial layers.

The nitride semiconductor wafer 10 has a substrate 1, a buffer layer 2 formed on a surface of the substrate 1, a semi-insulating nitride semiconductor layer 3 with high resistivity formed on the buffer layer 2, a channel layer 4 formed on the semi-insulating nitride semiconductor layer 3, and an electron supplying layer 5 formed on the channel layer 4.

The substrate 1, being an insulating substrate, is made of a material having a prescribed lattice constant and a prescribed thermal expansion coefficient. The insulating substrate includes a semi-insulating substrate or an insulation substrate. The semi-insulating substrate is, for example, SiC (silicon carbide) substrate, GaN (gallium nitride) substrate, and the insulation substrate is, for example, a sapphire substrate. Note that when an inexpensive substrate is used, the substrate 1 is sometimes an electroconductive substrate. The electroconductive substrate includes Si substrate, SiC substrate, and GaN substrate to which, for example, electroconductive dopant is supplied.

The buffer layer 2 is a lattice matching layer for growing the semi-insulating nitride semiconductor layer 3 with good crystallinitiy on the substrate 1, or a buffer layer for inhibiting a diffusion of impurities from the substrate 1. The buffer layer 2 is, for example, made of i-type GaN, being a nitride semiconductor.

The semi-insulating nitride semiconductor layer 3 is a nitride semiconductor layer with high resistivity for improving crystallinity of a semiconductor film that grows thereon epitaxially. The semi-insulating nitride semiconductor layer 3 can be made of, for example, gallium nitride (GaN) or aluminium nitride (AlN), or nitride mixed crystal of gallium and aluminium (AlGaN). Further, the semi-insulating nitride semiconductor layer 3 can also be made of a nitride mixed crystal of gallium and indium (InGaN), or a nitride mixed crystal of aluminium and indium (InAlN), or a nitride mixed crystal of gallium, aluminium, and indium (AlGaInN). In an example shown in the figure, a case of a semi-insulating GaN layer is shown.

The channel layer 4 is formed by epitaxial growth on the semi-insulating nitride semiconductor layer 3. The channel layer 4 is composed of the nitride semiconductor layer. In the example shown in the figure, a case of i-type GaN channel is shown. The electron supplying layer 5 is made of a material having higher resistivity than the resistivity of the channel layer 4. In the example shown in the figure, a case of i-type AlGaN layer is shown, and more specifically, Al_{0.2}Ga_{0.8}N layer is shown.

Thus, the nitride semiconductor wafer 10 having the semi-insulating nitride semiconductor layer 3 can be prepared.

Further, an insulating film is formed on the surface of the electron supplying layer 5 of the nitride semiconductor wafer 10, and a part thereof is etched to form ohmic source electrode 6, ohmic drain electrode 7, and schottky gate electrode 8. Whereby, FET 13, being the nitride semiconductor device shown in FIG. 2 can be fabricated.

Here, the semi-insulating nitride semiconductor layer 3 with high resistivity necessary for obtaining excellent characteristics of the nitride semiconductor wafer and the nitride semiconductor device will be described in detail according to this embodiment.

In this embodiment, by defining the resistivity of the semi-insulating nitride semiconductor layer 3 and defining its film thickness, the nitride semiconductor layer 3 having stable semi-insulating properties is realized. Note that the term: “semi-insulating” of the semi-insulating nitride semiconductor layer generally does not show an absolute range of the resistivity. In many cases, the “semi-insulating” is used in the meaning that relative difference of the resistivity from other part of a device is shown, and the same thing can be said for the term: “high resistivity”. In this embodiment, the nitride semiconductor layer having resistivity of about 10 kΩcm or more at a room temperature is treated by being called “semi-insulating”.

In the FET (Field Effect Transistor) or HFET (Hetero-FET), being a modified example of FET, reduction of a drain leak current in pinch-off is strongly requested. The drain leak current means a drain current that flows when the device is turned-off by adding a pinch-off voltage to a gate electrode, and if a large quantity of drain leak current flows, it can not be said that the device is in an off-state. Therefore, an operation failure of the device occurs.

The drain leak current is caused by leak of a current not from the channel layer 4 but from the semi-insulating nitride semiconductor layer (high resistance layer) 3 under the channel layer 4, and is generally caused when the resistivity of the high resistance layer is insufficient. However, a required resistivity is not clear, and the higher resistivity would be better. However, as described above, actually the semi-insulating properties are unstable in terms of productivity, and there is a limit in the high resistivity that can be realized. As a result, generally, the semi-insulating nitride semiconductor layer having several dozen kΩcm or more is recognized as an excellent product once, and finally is determined accordingly by actually fabricating a FET device. Therefore, a failure rate of the device is high, thus generating a problem such as deteriorated yield of the device.

In this embodiment, it is clarified that not only the resistivity but also the film thickness of the high resistance layer is an important element, from a relation between the drain leak current suitable for an actual device structure and the resistivity, to thereby clearly show the target resistivity to be achieved without unnecessarily increasing the resistivity, and define the film thickness.

An FET device has a FET structure, which is a so-called lateral device in which the current flows in parallel to the substrate, and therefore the film thickness is an important element together with the resistivity. Here, there is a concept of a sheet resistance including the film thickness in the resistivity. However, an important point of the FET structure is that a thinner film thickness receives a strong influence from the substrate or a front surface side channel layer, and a different point is that there is no such a concept in the sheet resistance. Namely, in the sheet resistance, even in a case of a double film thickness, approximately the same sheet resistance is obtained if the resistivity is a double volume resistivity. However, actually a thinner film thickness is more preferable due to an influence from the substrate and the front surface side channel layer, from a viewpoint of inhibiting the drain leak current. This point is clear from examples as will be described later. Accordingly, in order to inhibit the drain leak current, it might be necessary that not the sheet resistance but the film thickness and the resistivity are independently decided.

As a result of the examination from this viewpoint, according to this embodiment, when the substrate has insulating properties like sapphire or semi-insulating SiC, it is suitable to set the film thickness to about 0.1 μm to 1.5 μm, and the resistivity at this time needs to be set to 10 MΩcm or more. If the film thickness is set thicker than 1.5 μm, a lower limit resistivity needs to be further increased. However, for example, it might be extremely difficult to stably produce the semi-insulating nitride semiconductor layer having the resistivity largely exceeding 100 MΩcm, thus inviting the deterioration of a production yield of an epitaxial wafer (example A).

Further, when a substrate such as p-type Si electroconductive substrate is used as the substrate, stability can not be obtained unless a minimum film thickness is set to 0.5 μm or more due to some influence from the substrate. However, an upper limit of the film thickness is 1.5 μm for the same reason as described above (example B).

Accordingly, in this embodiment, in order to stably produce the semi-insulating nitride semiconductor layer having the resistivity of 10 MΩcm or more, preferably the resistivity is set to 10 MΩcm or more and 100 MΩcm or less and the film thickness is set to 0.1 μm or more and 1.5 μm or less, when the semi-insulating nitride semiconductor layer 3 is formed on the insulating substrate. Further, when the semi-insulating nitride semiconductor layer 3 is formed on the electroconductive substrate, the resistivity is preferably set to 10 MΩcm or more and 100 MΩcm or less, and the film thickness is preferably set to 0.5 μm or more and 1.5 μm or less. Further, in order to further stably produce the semi-insulating nitride semiconductor layer having the resistivity of 10 MΩcm or more, the film thickness of the semi-insulating nitride semiconductor layer 3 is preferably set to be smaller than 1 μm, irrespective of a substrate state whether the substrate is the insulating substrate or the electroconductive substrate.

Next, a manufacturing method of the nitride semiconductor wafer and the nitride semiconductor device according to this embodiment shown in FIG. 1 and FIG. 2 will be described. As the film-forming apparatus for growing a semiconductor layer, MOVPE (Metal Organic Vapor Phase Epitaxy) apparatus, HVPE (Hydride Vapor Phase Epitaxy) apparatus, or MBE (Molecular Beam Epitaxy) apparatus, etc., can be used. Here, explanation will be given for a case of using a more generally used MOVPE apparatus.

The semi-insulating substrate 1 is loaded into the MOVPE apparatus. The buffer layer 2 is grown on the semi-insulating substrate 1 by using the metal organic vapor phase epitaxy. Thereafter, semi-insulating GaN layer is grown on the buffer layer 2. Further, the GaN channel layer 4 is grown on the semi-insulating GaN layer, and thereafter the AlGaN electron supplying layer 5 is further grown on the GaN channel layer 4, to thereby manufacture the nitride semiconductor wafer having a lamination structure shown in FIG. 1. Further, the ohmic electrode and the schottky electrode are formed by vapor deposition or photolithography, etc., to thereby manufacture the HFET device shown in FIG. 2.

Here, in realizing the high resistivity of the semi-insulating GaN layer as described above, being an important element of this embodiment, nitrogen-containing gas with high purity so as not allow impurities to mixed into the film, and Ga-containing organic metal raw material are selected. Further, regarding not only a furnace of the film-forming apparatus but also a jig used in the furnace, washed one or heated one without water is used. Note that regarding a mechanism of higher resistance, residual impurities or specific defects, or composite defects of them are estimated to be related to the formation of the film. Although, this is not clarified at the present point, highest resistivity can be obtained in an initial use of the film-forming apparatus which is washed or heated without water, and as the number of times of using the apparatus is increased, the resistivity tends to be low. Therefore, by executing film formation according to the number of times of using the apparatus, target high resistivity is achieved step by step, provided that a level of the resistivity is in a range of 10 MΩcm to 100 MΩcm.

### Advantages of the Embodiments

According to the embodiments of the present invention, one or more advantages described below can be exhibited.
(1) The target resistivity of the semi-insulating nitride semiconductor layer to be achieved is clearly shown and the film thickness is defined. Therefore, the nitride semiconductor layer having high insulating properties can be stably provided, and the nitride semiconductor wafer and the nitride semiconductor device having excellent characteristics can be provided.
(2) The relation between the resistivity and the film thickness capable of stably supplying the semi-insulating nitride semiconductor layer having sufficient high insulating properties is found. Therefore, the nitride semiconductor wafer and the nitride semiconductor device with excellent characteristics can be realized.
(3) The film thickness is taken into consideration in addition to the resistivity of the semi-insulating nitride semiconductor layer, and the film thickness of the semi-insulating nitride semiconductor layer is defined as 0.1 μm or more and 1.5 μm or less. Therefore, the nitride semiconductor layer having high insulating properties can be stably obtained, even in a case that the resistivity is 10 MΩcm or more and 100 MΩcm or less.
(4) The semi-insulating properties of the nitride semiconductor layer having an influence on the field effect transistor characteristics, and particularly an allowable range of the resistivity, being an important element of reducing the drain leak current, are defined from an aspect of the film thickness. Therefore, the nitride semiconductor wafer or the nitride semiconductor device having the nitride semiconductor layer with high insulating properties and excellent low drain leak current can be stably manufactured.

In addition, of course the present invention can be variously modified and executed in a range not departing from a gist of this invention. For example, the nitride semiconductor device further having the nitride semiconductor layer, being a functional semiconductor layer, on the aforementioned nitride semiconductor wafer, can also be fabricated. Further, when the electroconductive substrate is used for the substrate, the leak current to the substrate is inhibited by the semi-insulating nitride semiconductor layer having sufficiently high insulating properties formed on the electroconductive substrate. Therefore, the nitride semiconductor wafer and the nitride semiconductor device having excellent characteristics at a low cost can be realized. Further, in the embodiments of the present invention, the field effect transistor such as FET and HFET has been explained. However, the present invention is not limited thereto, and can be utilized for a semiconductor light emitting element and a semiconductor light receiving element such as a semiconductor laser (LD) and LED.

### EXAMPLES

The present invention will be described based on specific examples A to C. Any one of the semiconductor layers of the wafer of the examples was formed by using a metal organic vapor phase epitaxy method. The gas used here is carrier gas (H₂) or ammonia gas (NH₃), etc. Further, as an organic metal raw material gas, trimethyl-gallium (TMG), trimethyl-aluminium (TMA), and trimethyl-indium (TMI), etc., can be used.

### Example A

The device was manufactured as follows, regarding three kinds of insulating substrates. The buffer layer composed of a nucleus generation layer and AlN layer was grown by about 0.1 μm to 0.3 μm, on semi-insulating SiC substrate surface c with diameter of 6 inches, or on semi-insulating GaN substrate surface c with diameter of 2 inches, or on sapphire substrate surface c with diameter of 6 inches. As a growth method of the buffer layer, first a crystal nucleus (nucleus generation layer) with high density was formed on the substrate, and next, the AlN layer was grown with this crystal nucleus as a nucleus of growth.

After the buffer layer was grown, a GaN high resistance layer (semi-insulating nitride semiconductor layer) of this example was grown at 1,050° C. Crystal growth conditions of the GaN high resistance layer are set: total pressure in a growth furnace; 1013 hPa, crystal growth rate; 80 nm/min, and V/III rate; 1473. Further, the film thickness of the GaN resistance layer was variously changed from 0.05 μm to 1.8 μm.

The raw material with high purity was selected so that donor impurities are not mixed into the film, in realizing high resistivity of the GaN high resistance layer, being an important element here. Concentration of the impurities was a detection limit or less in an impurity analysis of the raw material itself, and therefore a high purity raw material with high resistivity was used by evaluating an actually formed crystal. Further, regarding the jig used in the furnace as well, the jig washed at the growth temperature until the impurities were not discharged, or the jig heated without water in a vacuum state or in a hydrogen atmosphere was used. Thus, the high resistivity of the GaN high resistance layer of 8 Mμcm to 110 MΩcm was realized.

Further, after growth of about 0.1 μm of the GaN channel layer at 1,100° C., Al_{0.2}Ga_{0.8}N layer with 20% of Al composition was grown with a thickness of 0.03 μm, to thereby manufacture the nitride semiconductor wafer having a lamination structure shown in FIG. 1.

Further, ohmic electrodes and schottky electrode were formed on the electron supplying layer 5 of the nitride semiconductor wafer by vapor deposition or photolithography, etc., to thereby manufacture the HFET device shown in FIG. 2.

Table 1 shows results of examining the influence of the resistivity of the HFET device thus formed on the production yield rate of the device, and the influence of the leak current to the film thickness on the production yield of rate of the device. In examples 1 to 9, and comparative examples 1 to 8, as shown in table 1 respectively, 10 epitaxial wafers having high resistance GaN layer with prescribed resistivity and thickness, are grown by using the aforementioned three kinds of insulating substrates, and thereafter the device for each wafer is manufactured and evaluated.

TABLE 1

| | | | Film | Leak | Production |
|---|---|---|---|---|---|
| | Kind of | Resistivity | thickness | current | yield of |
| | substrate | (MΩcm) | (μm) | (μA/mm) | device |
| Example 1 | SiC | 10 | 0.1 | 0.21~0.30 | 93 |
| | GaN | | | 0.21~0.25 | 97 |
| | Sapphire | | | 0.23~0.34 | 91 |
| Example 2 | SiC | 50 | 0.1 | 0.05~0.07 | 91 |
| | GaN | | | 0.04~0.05 | 95 |
| | Sapphire | | | 0.06~0.08 | 90 |
| Example 3 | SiC | 100 | 0.1 | 0.03~0.04 | 92 |
| | GaN | | | 0.02~0.03 | 96 |
| | Sapphire | | | 0.03~0.05 | 91 |
| Example 4 | SiC | 10 | 1 | 0.65~0.73 | 96 |
| | GaN | | | 0.65~0.70 | 99 |
| | Sapphire | | | 0.68~0.76 | 94 |
| Example 5 | SiC | 50 | 1 | 0.15~0.25 | 98 |
| | GaN | | | 0.14~0.16 | 100 |
| | Sapphire | | | 0.16~0.28 | 95 |
| Example 6 | SiC | 100 | 1 | 0.08~0.12 | 99 |
| | GaN | | | 0.07~0.08 | 100 |
| | Sapphire | | | 0.09~0.13 | 98 |
| Example 7 | SiC | 10 | 1.5 | 0.87~0.95 | 97 |
| | GaN | | | 0.87~0.88 | 99 |
| | Sapphire | | | 0.88~0.99 | 95 |
| Example 8 | SiC | 50 | 1.5 | 0.17~0.19 | 98 |
| | GaN | | | 0.17~0.18 | 100 |
| | Sapphire | | | 0.17~0.21 | 96 |
| Example 9 | SiC | 100 | 1.5 | 0.09~0.11 | 100 |
| | GaN | | | 0.09~0.10 | 100 |
| | Sapphire | | | 0.10~0.13 | 99 |
| Com. Ex. 1 | SiC | 8 | 0.05 | 0.25~0.42 | 10 (*) |
| | GaN | | | 0.25~0.28 | 20 (*) |
| | Sapphire | | | 0.28~0.47 | 0 (*) |
| Com. Ex. 2 | SiC | 8 | 1 | 0.95~1.09 | 45 |
| | GaN | | | 0.95~1.06 | 50 |
| | Sapphire | | | 0.97~1.14 | 25 |
| Com. Ex. 3 | SiC | 8 | 1.8 | 3.90~4.34 | 0 |
| | GaN | | | 3.95~4.16 | 0 |
| | Sapphire | | | 4.07~4.44 | 0 |
| Com. Ex. 4 | SiC | 50 | 0.05 | 0.15~0.22 | 0 (*) |
| | GaN | | | 0.15~0.18 | 0 (*) |
| | Sapphire | | | 0.18~0.27 | 0 (*) |
| Com. Ex. 5 | SiC | 50 | 1.8 | 0.91~1.24 | 25 |
| | GaN | | | 0.91~1.18 | 30 |
| | Sapphire | | | 0.94~1.28 | 20 |
| Com. Ex. 6 | SiC | (Failure of | 0.05 | — | 0 |
| | | growth) | | | |
| | GaN | 110 | | 0.05~0.08 | 0 (*) |
| | Sapphire | (Failure of | | — | 0 |
| | | growth) | | | |
| Com. Ex. 7 | SiC | 110 | 1 | 0.75~3.09 | 60 |
| | GaN | 110 | | 0.75~2.06 | 70 |
| | Sapphire | (Failure of | | — | 0 |
| | | growth) | | | |
| Com. Ex. 8 | SiC | 110 | 1.8 | 0.95~2.49 | 55 |
| | GaN | | | 0.85~2.39 | 65 |
| | Sapphire | | | 1.25~2.06 | 0 (*) |

(*) Remarkable failure of device characteristics (such as on-resistance) is great.
Com. ex. = Comparative example

Note that with the aforementioned device structure, the resistivity of the GaN high resistance layer was hardly measured, and therefore simultaneously with the manufacture of the device, the resistivity was measured by a two-terminal method by manufacturing a structure that a layer other than the GaN channel layer in FIG. 1 was not grown. Further, the leak current was measured as a quantity of the drain leak current to the film thickness of the high resistance layer, by measuring the FET characteristics using the device of FIG. 2.

In calculating the production yield, as device with a drain leak current being 1 μA/mm or less is regarded as passing an evaluation, out of the devices with a drain current being normally modulated by application of gate bias, namely the devices that function as FET. Then, the ratio of the passed devices out of the acquired devices is set as the production yield. According to a device structure in this example, the on-current is ordinarily about 0.3 A/mm to 1.0 A/mm, and therefore the device with the on-current being less than 0.1 A/mm is hardly used. Further, if the drain leak current exceeds 1 μA/mm, loss during switching operation is increased, thus losing the characteristics as a GaN device. Therefore, such a device is also hardly used.

Further, as will be described later, when the high resistance layer grows in such a manner as having an influence on the growth of the growth layer thereon, namely, the growth of the channel layer, for example, a problem in terms of a service life occurs such as lowering of the on-current, or gradually lowering of the current during operation, thus not allowing the device to be operated as a normal FET. Therefore, failure of the device occurs irrespective of the characteristics of the high resistance layer, and the production yield is deteriorated.

Results showing the influence of the film thickness and the resistivity on the ratio of the production yield of the device is shown in table 2, focusing on the ratio of the production yield of the device in the table 1. There is a little difference in leak currents depending on the kind of the substrate, and therefore three substrate kinds in each example and each comparative example are collectively shown, and the device with the production yield of 90% or more is regarded as pass (∘) and the device with production yield of less than 90% is regarded as failure (×).

TABLE 2

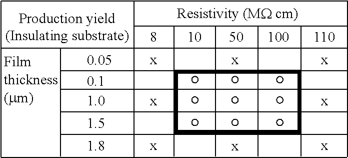

From the results of the table 1 and the table 2, it is found that with the film thickness of 1.8 μm or more, the production yield is deteriorated (drain leak current is increased). Further, it is found that with the film thickness of 0.1 μm or more, the resistivity of 10 MΩcm or more is required. Note that the sample having the resistivity of 110 MΩcm or more can not stably grow. In this case, the production yield in the crystal growth is 50% or less, thus decreasing the ratio of the production yield of the device. In a case of further lower resistivity of 10 MΩcm to 100 MΩcm, the sample can grow normally with a wafer production yield of 90% to 100%, and the ratio of the production yield of the device is also high.

In a case of the film thickness thinner than 0.1 μm, a quality of the GaN crystal of the channel layer is deteriorated, and a gain and the other transistor characteristics are defective, thus inviting the deterioration of the production yield. Accordingly, it can be considered that 0.1 μm is a lower limit of the film thickness.

From the table 2, a suitable range of not allowing the leak current to occur with the high production yield, is hardly defined or grasped uniformly. Therefore, in order to define the suitable range, results of the influence of the leak current in addition to the influence of the resistivity and the film thickness, are shown in table 3 in such a manner as being overlapped on the table 2, focusing on the leak current. A range of the leak current in each column collectively shows the kinds of the substrate. In the table 3, a portion surrounded by a frame shows the range of a low leak current with high production yield. Here, an upper limit of the suitable leak current is set to 0.76 μA/mm.

TABLE 3

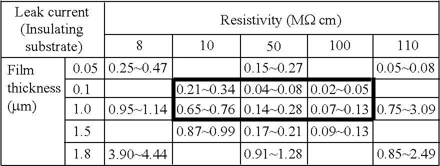

From the results, it is found that regarding the semi-insulating nitride semiconductor layer on the insulating substrate, if the resistivity is 10 MΩcm or more and 100 MΩcm or less, and the film thickness is 0.1 μm or more and 1.5 μm or less, an excellent device with small drain leak current can be stably manufactured. Further, it is found that preferably if the film thickness is smaller than 1 μm, an excellent device with low drain leak current can be stably manufactured.

### Example B

The nucleus generation layer and the AlGaN layer were grown on a 6-inch p-type Si substrate (111) plane by using the metal organic vapor phase epitaxy using ammonia gas and organic metal raw materials, and thereafter the GaN high resistance layer (semi-insulating nitride semiconductor layer) of this example was grown at 1050° C. thereon with various thicknesses. A sample preparation procedure thereafter is the same as shown in the example A. Results thereof are summarized in table 4. As shown in the table 4 respectively, examples 10 to 18 and comparative examples 9 to 16 show the results of growing 10 sheets of epitaxial wafers having the high resistance GaN layer with prescribed resistivity and thickness, and thereafter manufacturing the device for each of the epitaxial wafers and evaluating the device.

TABLE 4

| | | Film | Leak | Ratio of |
|---|---|---|---|---|
| | Resistivity | thickness | current | production |
| | (MΩcm) | (μm) | (μA/mm) | yield (%) |
| Example 10 | 10 | 0.5 | 0.40~0.47 | 95 |
| Example 11 | 50 | 0.5 | 0.15~0.21 | 99 |
| Example 12 | 100 | 0.5 | 0.08~0.10 | 97 |
| Example 13 | 10 | 1.0 | 0.65~0.73 | 98 |
| Example 14 | 50 | 1.0 | 0.20~0.29 | 100 |
| Example 15 | 100 | 1.0 | 0.11~0.17 | 98 |
| Example 16 | 10 | 1.5 | 0.85~0.99 | 95 |
| Example 17 | 50 | 1.5 | 0.28~0.46 | 98 |
| Example 18 | 100 | 1.5 | 0.18~0.27 | 94 |
| Com. ex. 9 | 8 | 0.3 | 0.45~1.09 | 35 |
| Com. ex. 10 | 8 | 1.0 | 1.15~2.06 | 0 |
| Com. ex. 11 | 8 | 1.8 | 1.97~2.24 | 0 |
| Com. ex. 12 | 50 | 0.3 | 0.25~1.39 | 60 |
| Com. ex. 13 | 50 | 1.8 | 0.95~2.06 | 25 |
| Com. ex. 14 | 110 | 0.3 | 0.15~1.09 | 70 |
| Com. ex. 15 | 110 | 1.0 | 0.85~2.49 | 10 |
| Com. ex. 16 | 110 | 1.8 | 1.15~3.06 | 0 |

Com. ex. = Comparative example

Results showing the influence of the film thickness and the resistivity on the ratio of the production yield of the device is shown in table 5, focusing on the ratio of the production yield of the device in the table 4. The device with the production yield being 90% or more is regarded as pass (∘) and the device with production yield being less than 90% is regarded as failure (×).

TABLE 5

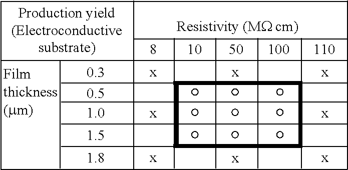

Similarly to the results of the example A, from the results of the table 4 and the table 5, it is found that when the film thickness is thicker than 1.5 μm, a sufficient resistivity can not be secured, and the production yield is deteriorated (drain leak current is increased). Further, similarly, it is found that the resistivity of 10 MΩcm or more is required. Note that when the film thickness is thinner than 0.5 μm, a morphology of a crystal surface is obviously deteriorated, thus causing the failure of the gain and the other transistor characteristics, thereby inviting the deterioration of the production yield. Accordingly, it can be considered that a lower limit of the film thickness is 0.5 μm.

Based on the table 4, results showing the influence of the leak current in addition to the influence of the film thickness and the resistivity on the ratio of the production yield of the device is shown in table 6 in such a manner as being overlapped on the table 5, focusing on the leak current. In the table 4, a portion surrounded by a frame shows a range where the leak current is hardly generated with high production yield. Here, an upper limit of a suitable leak current is set to 0.76 μA/mm.

TABLE 6

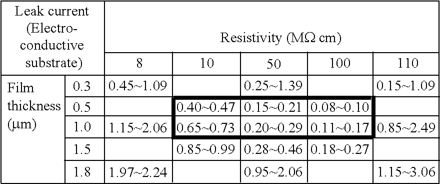

From the results, it is found that regarding the semi-insulating nitride semiconductor layer on the electroconductive substrate, if the resistivity is 10 MΩcm or more and 100 MΩcm or less, and the film thickness is 0.5 μm or more and 1.5 μm or less, the excellent device with small drain leak current can be stably manufactured. Further, if the film thickness is smaller than 1 μm, the excellent device with low drain leak current can be stably manufactured.

### Example C

The nucleus generation layer and the AlN layer were grown on a 6-inch sapphire substrate c plane by using the metal organic vapor phase epitaxy using ammonia gas and organic metal raw materials, and thereafter the high resistance layer (semi-insulating nitride semiconductor layer) of any one of GaN, AlGaN, InAlN, and AlGaInN was grown thereon at 1050° C. A sample preparation procedure thereafter is the same as shown in the example A, and the nitride semiconductor wafer having the lamination structure shown in FIG. 3 was manufactured, and the HFET device similar to that of FIG. 2 was further manufactured. Note that FIG. 3 shows a case that the high resistance layer is a semi-insulating AlGaInN layer 13.

Regarding each HFET device, a relation between the kind and the resistivity of the high resistance layer, and the drain leak current, was examined. In any one of the aforementioned materials, reflecting a state that a bandgap is larger than GaN, the drain leak current is more decreased than a case of the GaN shown in the example A. Accordingly, it is found that a sufficient resistivity can be secured, and the drain leak current can be suppressed, provided that the film thickness is 1.5 μm or less. Further, it is sufficient to set the resistivity to 10 MΩcm or more. Note that if the film thickness is thinner than 0.1 μm, flatness of the growth surface is deteriorated, thus causing the failure of the transistor characteristics. Accordingly, it can be considered that this point is also similar to a case shown in the example A in which the high resistance GaN layer is provided.

What is claimed is:

1. A nitride semiconductor wafer, having a semi-insulating nitride semiconductor layer on an insulating substrate, with a resistivity of 10 MΩcm or more and 100 MΩcm or less, a film thickness of 0.1 μm or more and 1.5 μm or less.

2. A nitride semiconductor wafer having a semi-insulating nitride semiconductor layer on an electroconductive substrate, with a resistivity of 10 MΩcm or more and 100 MΩcm or less, and a film thickness of 0.5 μm or more and 1.5 μm or less.

3. The nitride semiconductor wafer according to claim 1, wherein the film thickness of the semiconductor layer is preferably smaller than 1 μm.

4. The nitride semiconductor wafer according to claim 2, wherein the film thickness of the semiconductor layer is preferably smaller than 1 μm.

5. The nitride semiconductor wafer according to claim 1, wherein the semiconductor layer is made of gallium nitride or aluminium nitride, or a nitride mixed crystal of gallium and aluminium.

6. The nitride semiconductor wafer according to claim 2, wherein the semiconductor layer is made of gallium nitride or aluminium nitride, or a nitride mixed crystal of gallium and aluminium.

7. The nitride semiconductor wafer according to claim 1, wherein the semiconductor layer is made of a nitride mixed crystal of gallium and indium, or a nitride mixed crystal of aluminium and indium, or a nitride mixed crystal of gallium, aluminium, and indium.

8. The nitride semiconductor wafer according to claim 2, wherein the semiconductor layer is made of a nitride mixed crystal of gallium and indium, a nitride mixed crystal of aluminium and indium, or a nitride mixed crystal of gallium, aluminium, and indium.

9. The nitride semiconductor wafer according to claim 1, wherein the insulating substrate is made of any one of silicon carbide, gallium nitride, and sapphire.

10. The nitride semiconductor wafer according to claim 2, wherein the electroconductive substrate is made of silicon.

11. A nitride semiconductor device, wherein a nitride semiconductor layer is further provided on the nitride semiconductor wafer of claim 1.

12. A nitride semiconductor device, wherein a nitride semiconductor layer is further provided on the nitride semiconductor wafer of claim 2.
